(19) United States
(12) Patent Application Publication
(10) Pub. No.: US 2003/0013314 A1
(43) Pub. Date: Jan. 16, 2003

(54) Method of reducing particulates in a plasma etch chamber during a metal etch process

(76) Inventors: Chentsau Ying, Cupertino, CA (US); Jeng H. Hwang, Cupertino, CA (US); Yong Deuk Ko, Kyonggi (KR); Se Jin Oh, Suwon (KR); Chan Ouk Jung, Seoul (KR)

Correspondence Address: APPLIED MATERIALS, INC., 2881 SCOTT BLVD. M/S 2061, SANTA CLARA, CA, 95050, US

(21) Appl. No.: 09/991,166

(22) Filed: Nov. 16, 2001

Related U.S. Application Data
(63) Continuation-in-part of application No. 09/918,671, filed on Jul. 27, 2001.

(30) Foreign Application Priority Data
Jul. 6, 2001 (KR) 10-2001-40309

(51) Int. Cl. H01L 21/302; H01L 21/461

(52) U.S. Cl. 438/710

(57) ABSTRACT

Nonvolatile etch byproduct contaminants are generated during etching processes for forming electrodes of storage capacitors for very high density future memory cells, such as ferroelectric random access memory (FeRAM) cells. These contaminants include significant quantities of metals and metal compounds. In order to prevent undesirable metal etch byproduct particulates from adversely affecting subsequent etching processes performed in the chamber, the plasma metal etch chamber is seasoned by placing a substrate in the chamber, then exposing the substrate and interior surfaces of the chamber to a seasoning plasma generated from a source gas that includes at least one principal etchant gas used during an etch process which produced the nonvolatile etch byproducts. The method is performed at a substrate temperature that is equal to or greater than a substrate temperature at which the nonvolatile etch byproducts were produced. Exposure of the substrate to the seasoning plasma generates an entrapment and adhering material which adheres the nonvolatile etch byproducts to interior chamber surfaces.

### STATEMENT OF RELATED APPLICATION

This application is a continuation-in-part of U.S. patent application Ser. No. 09/918,671, filed Jul. 27, 2001, which is currently pending.

### BACKGROUND OF THE INVENTION

1. Field of the Invention

The present invention pertains to a method of reducing contaminants in a semiconductor processing environment. In particular, the present invention pertains to a method of preventing particulates generated from metal etch byproducts, which are nonvolatile at temperatures at which the metal is etched, from adversely affecting a subsequent etch process performed in a plasma etch chamber.

2. Brief Description of the Background Art

Ferroelectric random access memory (FeRAM) cells have been introduced as a future generation of very high density memory cells, potentially at the giga bit level and beyond. Storage capacitors in such FeRAM cells require new materials for their electrodes and dielectrics in order to meet increasingly small design requirements. Recently, high dielectric constant (k>20) materials, such as barium strontium titanate (BST), lead zirconium titanate (PZT), strontium bismuth tantalate (SBT), tantalum pentoxide (Ta₂O₅), have been evaluated as candidates for dielectric materials for FeRAM cells. For example, PZT has been found to have excellent characteristics for use in very high density storage capacitors. When storage capacitors are formed with a PZT layer sandwiched between electrodes made of metals such as aluminum and aluminum alloys, a longer data retention time is achieved than with conventional storage capacitors. However, the retention time gradually decreases, requiring frequent data refresh operations to be performed in order to safely retain data within the storage capacitors. Therefore, conventionally used electrode metals have proven to be unacceptable for use with PZT in the fabrication of storage capacitors for use in future generation high density memory cells.

There are two basic requirements for storage capacitors for use in very high density memory cells: 1) longer retention time; and 2) tolerance to a large number of data refresh operations without significant deterioration of the charge characteristics during the lifetime of the memory cells. For example, for non-volatile memory (NVM) applications, the desired data retention time is over 10 years; for DRAM applications, data refresh operations may be performed more than one million times over the lifetime of the storage capacitors.

Recently, noble metals, such as platinum and iridium, have been evaluated as new materials for electrodes of storage capacitors. Noble metals are known to have several advantages over conventional metals such as aluminum, including: 1) forms chemically and physically stable interfaces with high dielectric constant materials, such as PZT; 2) forms good electrical contacts with other metals used for interconnection; and 3) stable under high temperature O₂ ambient processes.

Storage capacitors formed with noble metals (such as iridium and platinum) as electrodes and high dielectric constant materials (such as PZT, SBT, and Ta₂O₅) show excellent characteristics in terms of data retention time and allowable refresh operations. As a result, storage capacitors formed with high dielectric constant materials and noble metals are viable candidates for the future generation of storage capacitors.

With respect to future data storage technologies, an alternative to the FeRAM cell is the magnetoresistive random access memory (MRAM) cell. MRAM technology is based on the integration of silicon complementary metal oxide semiconductor (Si CMOS) technology with magnetic memory elements. MRAM is nonvolatile and has unlimited read and write endurance. Recent advances in Giant Magnetoresistance (GMR) and Magnetic Tunnel Junction (MTJ) materials give MRAM the potential for high speed, low operating voltage, and high density. MRAM cells incorporate magnetoresistive materials such as nickel-iron, cobalt-iron, and nickel-iron-cobalt alloys. For example, two kinds of current-in-plane (CIP) GMR structures are the spin valve and the pseudo spin valve (PSV). The PSV structure consists of two magnetic layers (e.g., NiFeCo and CoFe) with copper as an interlayer.

One of the problems encountered with the production of future generation storage capacitors is that a significant number of nonvolatile contaminants are generated during metal etching processes. These particulates generally remain inside the plasma etch chamber after the completion of the metal etch process. For example, iridium particulates make up a large portion of the particulates observed in a plasma etch chamber subsequent to the formation of a PZT/iridium storage capacitor. FIG. 5 shows the composition of particulates, measured by energy dispersion spectroscopy (EDS), on a wafer surface after processing in a plasma etch chamber. Iridium particulates from etching of a PZT/iridium storage capacitor remain even after a purge operation, and can seriously affect subsequent wafer processing operations.

The build-up of metal particulates on chamber surfaces can lead to an uneven power supply to the plasma, resulting in variable plasma conditions within the etch chamber. Variable plasma conditions can have a destabilizing effect on etch processes performed within the chamber, which can negatively impact etching performance parameters, such as etch rate, etch profile, and etch uniformity. The electrical performance of devices produced using that etch chamber may ultimately be affected. Further, the presence of particulate contaminants may render a portion of the devices on the substrate inoperable, decreasing product yield.

The mean time between chamber cleaning operations is typically specified as Mean Wafers Between Cleans, MWBC. An economically feasible MWBC is about 400 to 500 wafers between cleaning operations, with the industry goal for mass production as high as 1000 wafers between cleaning operations, assuming a single wafer per etch process per chamber. Due to the generation of metal particulates during the etch process, the use of noble metal compounds in the formation of electrodes results in a significant reduction in the MWBC, which may be as low as 10 wafers. This makes forming electrodes using noble metal compounds, in particular, economically impractical.

U.S. Pat. No. 6,020,035, to Gupta et al., discloses a method of depositing a seasoning layer on surfaces of a substrate processing chamber, to cover contaminants (primarily fluorine-containing) which may be absorbed within the walls of insulation areas of the chamber, and to block the release of these contaminants from chamber walls. Unfortunately, this conventional seasoning method was found to be ineffective at reducing the amount of free iridium and iridium compound particulates found floating within a plasma processing chamber after seasoning, even after cleaning with a purge gas.

Therefore, there is a need for a method of controlling undesirable residual metal particulates and metal compound particulates remaining within a plasma processing chamber, even after cleaning using methods currently known in the art.

### SUMMARY OF THE INVENTION

The present invention provides a method of preventing particulates generated from metal etch byproducts, which are nonvolatile at temperatures at which the metal is etched, from adversely affecting a subsequent metal etch process performed within the same plasma etch chamber. The method includes a seasoning process in which a plasma is used to generate a material which entraps and adheres byproducts from a metal etch process to process chamber walls and internal apparatus surfaces. By adhering metal etch byproduct contaminants to surfaces within the processing chamber, these contaminants are no longer as available to fall upon subsequent wafers (substrates) being processed within the chamber.

Surprisingly, the plasma used to generate the adhering material is generated from a source gas comprising at least one of the principal etchant gases used during the etch process which produced the nonvolatile etch byproducts which have contaminated the etch processing chamber. In addition to the etchant gas species, a source for an entrapment and adhering material is provided. In some instances, upon exposure of a substrate placed in the process chamber during seasoning, an entrapment and adhering material is generated which adheres the nonvolatile etch byproducts to interior chamber surfaces. The entrapment and adhering material may be a carbon-containing or silicon-containing matrix, which is typically generated by reaction of the seasoning plasma with a silicon-containing (such as silicon oxide or silicon nitride) or carbon-containing (such as photoresist) layer on the substrate. Alternatively, the source for the entrapment and adhering material may be a layer of a dielectric material, such as aluminum oxide, which is sputtered off the substrate and which forms a dielectric coating on interior chamber surfaces. A carbon-containing additive gas within the seasoning plasma may optionally provide a source for the entrapment and adhering material. In some instances, a carbon-containing additive gas may be used in the absence of a substrate with an adhering material on its surface.

In a first embodiment of the present invention, a substrate which provides a source of an entrapment and adhering material is placed inside a processing chamber and the substrate (as well as interior surfaces of the chamber) is exposed to a seasoning plasma generated from a source gas that includes at least one principal etchant gas which is typically used to etch a metal from which the byproducts were produced. The seasoning process is carried out at a substrate temperature that is equal to or greater than the substrate temperature at which the metal byproducts are typically produced. The chamber wall temperature is maintained at a temperature which is lower than the substrate temperature. Typically, the temperature of the chamber wall is at least 100° C. to 300° C. lower than the substrate temperature. The plasma source gas often includes Cl₂, a chlorine-containing compound, or combinations thereof. The seasoning method of the invention is performed for a time period sufficient that a subsequent measurement of particulate count on a monitor silicon wafer indicates an acceptable particulate count.

Subsequent to performing the chamber seasoning process, a 6-inch or 8-inch monitor wafer placed in the chamber to determine a particle count accumulation under particular monitoring conditions. Depending on the monitoring conditions, a typical acceptable particle count is less than about 20 particles per wafer. Reduction in metal particulates in the plasma etch chamber after performing the seasoning method to such a lowered particle count has enabled as many as 200 wafers to be processed between cleaning operations. The significant increase in MWBC results in reduced processing costs, as well as improved yields.

In certain cases, the chamber seasoning method of the invention has been shown to have a stabilizing effect on chamber conditions during a subsequent metal etch process, resulting in a consistent etch rate and improved etch profile and etch uniformity.

In a second embodiment, the method comprises exposing interior surfaces of the chamber to a seasoning plasma generated from a gas mixture comprising at least two gases selected from the group consisting of BCl₃, HBr, and CF_{4,}, for a time period sufficient that a subsequent measurement of particulate count on a monitor silicon wafer indicates an acceptable particulate count. In this embodiment, a substrate including a layer of iridium is placed in the plasma etch chamber and exposed to the seasoning plasma. CF₄ is added to the plasma source gas to provide for polymer formation, which entraps and adheres iridium particulates generated during the seasoning process and metal etch byproduct contaminants from previous etch processes to chamber apparatus surfaces.

Also disclosed herein is a method of forming a storage capacitor in a plasma etch chamber, comprising the following steps: a) exposing interior surfaces of the plasma etch chamber to a seasoning plasma generated from a gas mixture comprising at least two gases selected from the group consisting of BCl₃, HBr, and CF₄; b) purging the plasma etch chamber of remaining seasoning gas mixture; c) loading a substrate having at least one layer of a noble metal such as iridium or platinum formed thereon into the plasma etch chamber; and d) plasma etching the at least one layer of the noble metal.

Also disclosed herein is a method of forming a storage capacitor in a plasma etch chamber, comprising the following steps: a) loading a substrate having at least one layer of a noble metal such as iridium or platinum formed thereon into the plasma etch chamber; b) plasma etching the at least one layer of a noble metal; c) removing the substrate from the plasma etch chamber; d) cleaning the plasma etch chamber using a purge gas; and e) exposing interior surfaces of the plasma etch chamber to a seasoning plasma generated from a gas mixture comprising at least two gases selected from the group consisting of BCl₃, HBr, and CF₄.

### BRIEF DESCRIPTION OF THE DRAWINGS

FIG. 1 shows a representative decoupled plasma source (DPS) etch chamber 100, which is one of many etch chambers in which plasma etching and seasoning in accordance with the present invention may be performed.

FIG. 2 is a simplified, cross-sectional view of a next-generation storage capacitor 200.

FIGS. 3A-3J illustrate a step-by-step process for forming a storage capacitor of the kind shown in FIG. 2.

FIG. 4 is a schematic representing a scanning electron micrograph (SEM) 400 of a typical iridium particulate.

FIG. 5 is a graph 500 showing the composition of particulates, measured by energy dispersion spectroscopy (EDS), on a wafer that has been processed through a plasma etch chamber in which iridium-comprising materials were etched.

FIG. 6 is a graph 600 showing changes in iridium particulate counts over time, as cleaning and seasoning of the etch chamber are performed in accordance with the present invention.

### DETAILED DESCRIPTION OF THE EXEMPLARY EMBODIMENTS

Disclosed herein is a method of reducing particulates in a plasma etch chamber, where such particulates are generated from nonvolatile metal etch byproducts.

Exemplary processing conditions for performing the method of the invention are set forth below.

As a preface to the detailed description, it should be noted that, as used in this specification and the appended claims, the singular forms “a”, “an”, and “the” include plural referents, unless the context clearly dictates otherwise.

I. One Apparatus for Practicing the Invention

The exemplary embodiment etch processes described herein were carried out in a CENTURA® Integrated Processing System available from Applied Materials, Inc., of Santa Clara, Calif. The method may also be practiced in other metal etch processing chambers known in the industry.

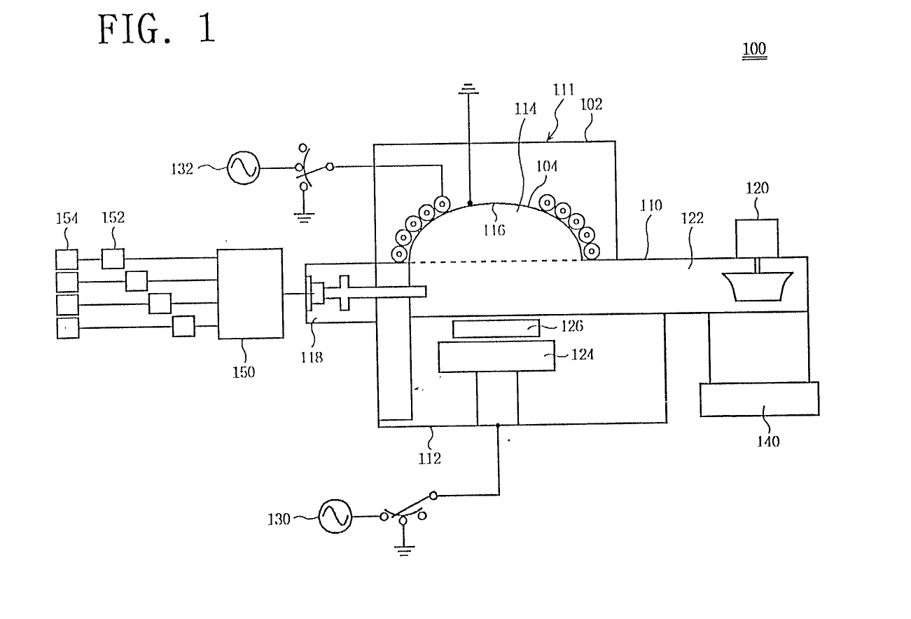

FIG. 1 is a schematic of an individual CENTURA® DPS™ etch chamber 100 of the type used in the Applied Materials' CENTURA® Integrated Processing System. The equipment shown in schematic in FIG. 1 includes a Decoupled Plasma Source (DPS) of the kind described by Yan Ye et al. at the proceedings of the Eleventh International Symposium of Plasma Processing, May 7, 1996, and as published in the Electrochemical Society Proceedings, Volume 96-12, pp. 222-233 (1996). The CENTURA® DPS™ etch chamber 100 is configured to be mounted on a standard CENTURA® mainframe.

The CENTURA® DPS™ etch chamber 100 consists of an upper chamber 110 and a lower chamber 112. Wafer processing is performed in the upper chamber 110, which is isolated from the lower chamber 112 during processing. The upper chamber 110 is smaller than conventional plasma etch chambers, resulting in smaller and fewer areas in which processing gases could be trapped. This also reduces the pumpdown time.

The upper chamber 110 includes four gas injection nozzles 118 (only one is shown), an endpoint window (not shown), and a manometer port (not shown). The gas injection nozzles 118 are located at each comer of the upper chamber 110. Processing gases are routed from a gas panel (not shown) to the bottom of the chamber 110, and through a V-block valve (not shown). After the V-block valve, a gas line (not shown) branches to each side of the upper chamber 110, and then branches again to each gas injection nozzle 118. Each of the four lines (not shown) is routed through the lower chamber 112 wall, up to the gas injection nozzles 118 of the upper chamber 110. During wafer processing, processing gases are injected through the gas injection nozzles 118 and into the DPS etch chamber 100.

The upper chamber further includes a pumping channel 122 and a throttle valve assembly 120, located at the end of the pumping channel 122. The throttle valve 120 controls chamber pressure by restricting the pumping orifice while gas is flowing into the upper chamber 110. Typically, the throttle valve 120 is of the plunger type, and is driven by a stepper motor (not shown).

A dome assembly 104 seals the upper chamber 110 during wafer processing. An RF coil, wrapped around the top of the dome 104, is excited by RF energy originating from a source RF generator (which is discussed further below). The dome 104 may be constructed of ceramic. A housing 102 fits over the dome 104 to prevent RF leakage and to shield the operator from UV light emissions. The dome 104 is heated or cooled, depending on the particular chamber activity.

The dome 104 needs to be maintained at a constant temperature, regardless of processing conditions, in order to prevent flaking off of deposited etch byproducts. Lamps (not shown) located in the midsection of the dome housing 102 are used to maintain the dome temperature when the chamber is not in use. When the chamber is not in use, lamp power is increased to keep the dome temperature from dropping below the chamber wall temperature. During processing, the lamp power output is reduced as the plasma heats up the dome 104.

In the lower chamber 112, a cathode 124 is positioned to move a wafer 126 into the upper chamber 110 for processing, while the lower chamber 112 remains sealed from the processing environment. The primary function of the lower chamber 112 is to transfer the wafer 126 between the robot blade (not shown) and the cathode 124 in a relatively clean environment. Since the double chamber design allows the upper chamber 110 to be removed and exchanged with another clean and prepared chamber, the chamber cleaning time is greatly reduced. Removal of the upper chamber 110 allows access to the lower chamber for maintenance. Both chambers must be at atmospheric pressure prior to the performance of maintenance operations. The etch chamber 100 is attached to a buffer chamber in a mainframe (not shown).

For independent control of the ion flux and ion acceleration energy, two RF power generators are provided: a bias RF generator 130 and a source RF generator 132. The bias RF generator 130 is coupled to the cathode 124 for biasing the cathode. The source RF generator 132 is coupled to the RF coil wrapped around the exterior surface of the dome 104, and is used to enhance the plasma, in order to achieve a high etch rate. The source RF generator 132 excites the processing gases and creates more reactive ions, so that a high density plasma is generated. The high density plasma produces more collisions between the face electrons and the gas molecules, resulting in a more ionized and reactive plasma.

The above-described etch chamber design permits independent control of the plasma ion flux and ion acceleration energy. The etch chamber 100 decouples the ion flux to the wafer 126 and the ion acceleration energy. This is accomplished by producing plasma via the inductive source 132. While the source RF generator 132 determines the ion flux, the bias RF generator 130 determines the ion acceleration energy. This chamber design provides fully independent ion density control, creating an enlarged processing window. Processing window refers to the amount by which process conditions can be varied without having a detrimental effect on the product produced. The larger the processing window, the greater change permitted in processing conditions without a detrimental effect on the product. Thus, a larger processing window is desirable, as this generally results in a higher yield of in-specification product.

The DPS etch chamber design allows high purity N₂ to flow through the upper and lower chambers (110, 112, respectively) as needed. Purging of the upper chamber with N₂ begins automatically when the process recipe is completed, in order to minimize particulate production. A continuous N₂ purge is used in the lower chamber 112 when the cathode 124 is in the down position. After upper chamber wafer processing is completed and the cathode 124 holding the wafer 126 starts to descend, the lower chamber N₂ purge flows from the lower chamber 112 through the upper chamber 110, to prevent processing gases from migrating to the lower chamber 112.

The system operation of the DPS etch chamber 100 is similar to that described in U.S. Pat. No. 6,121,161, to Rossman et al., in conjunction with a high density plasma (HDP) CVD system.

II. Applicability of the Method of Reducing Particulates in Metal Etch Chambers

As previously described herein, there is a need to reduce particulate contamination of substrates processed in metal etch chambers. A major source of particulate contaminants is etch process chamber surfaces, including internal apparatus in the chamber. The particulates are formed from metal etch byproducts which accumulate on process chamber surfaces. The particular contaminants depend on the metals being etched in the chamber. Some of the most problematic contaminants are due to the use of new metallic and metal-containing materials in the fabrication of semiconductor devices. These new metal-comprising materials produce etch byproducts which ar nonvolatile at the process temperatures at which etching of the metal-comprising materials is carried out.

By way of example, and not by way of limitation, fabrication of particular semiconductor devices which have demonstrated the need for a method of reducing particulates in metal etch chambers is described below. The method of reducing particulate contamination in a metal etch process chamber is useful for chambers used to fabricate other devices, as well as the devices which are described below.

III. Formations of a Storage Capacitor with PZT, Ir, and IrO₂

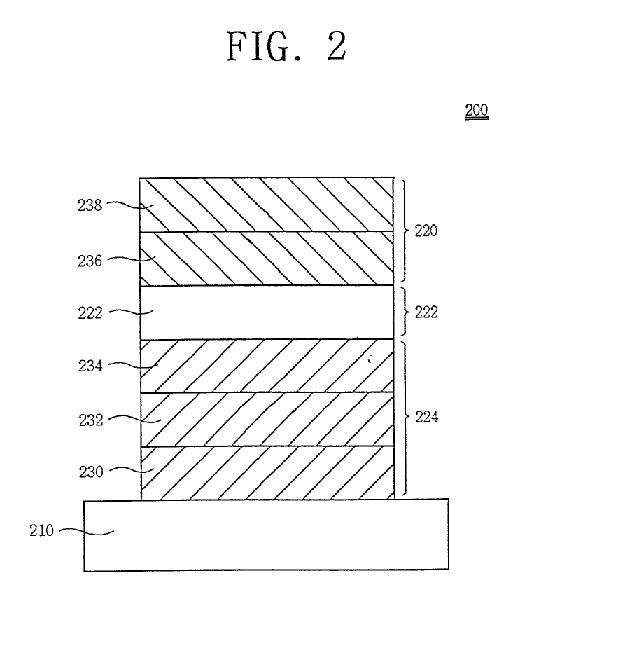

FIG. 2 shows a simplified, cross-sectional view of a next generation storage capacitor 200. As shown, layers of iridium 230, iridium oxide (IrO₂) 232, platinum (Pt) 234, PZT 222, iridium oxide 236, and iridium 238 are sequentially deposited on a substrate 210 to respectively form a lower electrode 224, PZT dielectric 222, and an upper electrode 220 of a storage capacitor 200. These layers of metals and dielectrics are formed by blanket deposition of metals and dielectrics over the entire surface of substrate 210 in the sequence described above. For the lower electrode, the layers of iridium 230, iridium oxide 232, and platinum 234 have thickness of about 1500 Å, 500 Å, and 1500 Å, respectively. The thickness of the PZT dielectric layer 222 is about 2000 Å. For the upper electrode 220, the layers of iridium oxide 236 and iridium 238 have thicknesses of about 300 Å and 1200 Å, respectively.

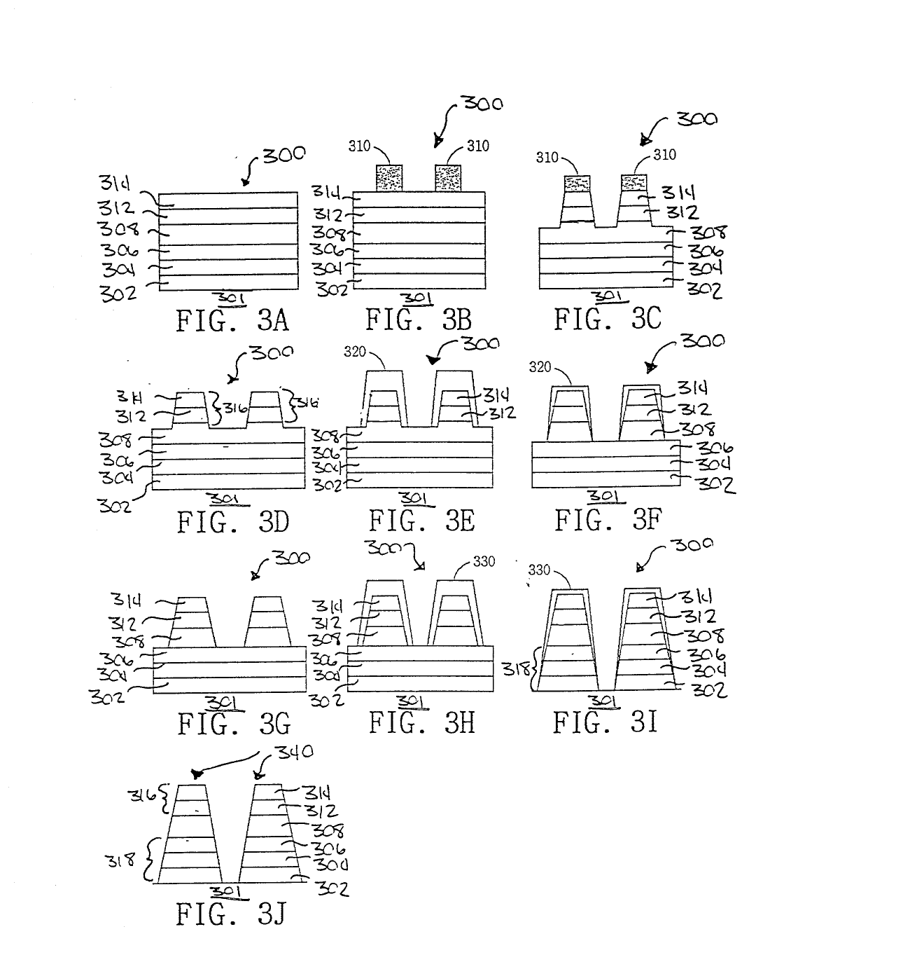

FIGS. 3A-3J illustrate a step-by-step process for forming a storage capacitor, as shown in FIG. 2. The process starts with the formation of a film stack 300, which consists of a set of metal and dielectric layers Ir 314/IrO₂ 312/PZT 308/Pt 306/IrO₂ 304/Ir 302, formed on substrate 301, as shown in FIG. 3A. Conventional metal and dielectric material deposition techniques known in the art, such as chemical vapor deposition (CVD) and physical vapor deposition (PVD) techniques, can be used to sequentially form the various layers.

A titanium nitride (TiN) hard mask 310, having a thickness of about 3000 Å, is then deposited over Ir layer 238 and patterned using conventional techniques known in the art, as shown in FIG. 3B. Ir and IrO₂ layers 314 and 312 are then pattern etched using techniques known in the art, to produce the structure shown in FIG. 3C. Residual TiN hard mask 310 remaining after etching of the Ir and IrO₂ layers 314 and 312 is then removed using techniques known in the art, thereby forming upper electrodes 316, as shown in FIG. 3D.

A photoresist layer is then formed over the top and side surfaces of upper electrodes 316 and is patterned to form a mask 320 using techniques known in the art (depending on the particular photoresist material used), to produce the structure shown in FIG. 3E. Then, the PZT dielectric 308 is pattern etched using techniques known in the art, as shown in FIG. 3F. Residual photoresist mask 320 remaining after etching of PZT dielectric layer 308 is then removed using techniques known in the art, as shown in FIG. 3G.

A TiN hard mask 330 is then formed over the top and side surfaces of upper electrodes 316 and PZT dielectric layer 308. The TiN hard mask 330 is patterned using techniques known in the art, as shown in FIG. 3H. Subsequently, a metal etch process is conducted in order to pattern etch the bottom three metal layers Pt 306/IrO₂ 304/Ir 302, down to the surface of substrate 301, to form lower electrodes 318, as shown in FIG. 3I. Residual titanium nitride hard mask 330 remaining after etching of metal layers 306, 304, and 302 is then removed by plasma etching, using etchant gases and process conditions known in the art, to form the structure shown in FIG. 3J.

FIG. 3J shows the final storage capacitors 340 formed using the above-described process. The width of top Ir layer 314 is about 0.7 μm, whereas bottom Ir layer 302 typically has a width of about 1.2-1.3 μm. The slope of the etched surface angle from the top to the bottom of storage capacitor 340 is about 70°. The duration of the entire storage capacitor fabrication process is about 120 seconds.

IV. Seasoning the Plasma Etch Chamber

Metal etch steps, such as those illustrated in FIGS. 3C, 3D, 3I, and 3J, take place inside the upper chamber 110 of the DPS etch chamber 100 shown in FIG. 1. During these metal etch processes, significant quantities of metal-comprising particulates are generated. The majority of these particulates may be removed by performing a nitrogen (N₂) purge cycle. However, a considerable amount of metal particulates still remain in the upper etch chamber 110 after performance of the N₂ purge cycle. These particulates adversely affect subsequent wafer processing.

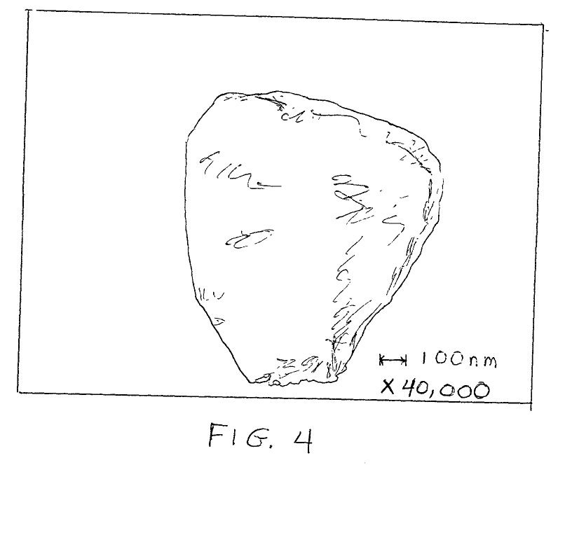

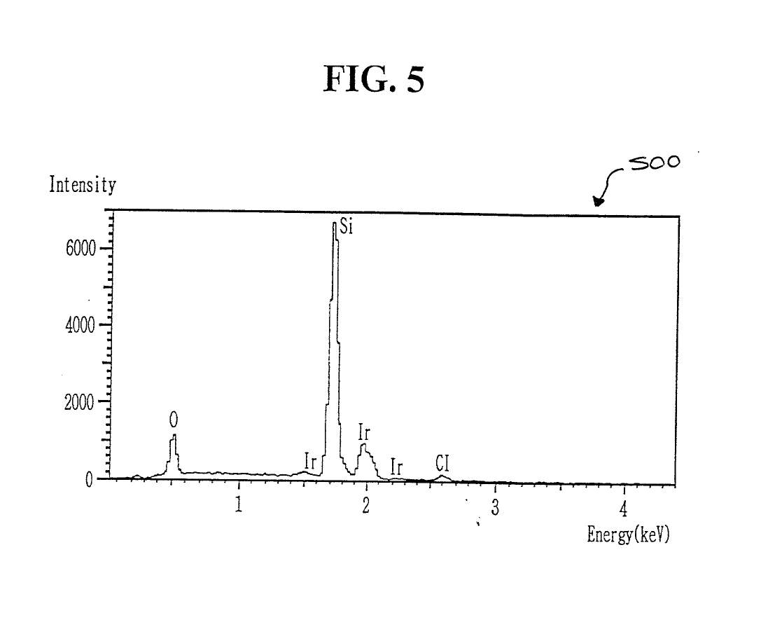

FIG. 4 is a scanning electron micrograph (SEM) 400 of a typical iridium particulate. Normally, any particulate size less than 75% of the minimum feature size is considered “harmless”. FIG. 5 is a graph 500 showing the composition of particulates, measured by energy dispersion spectroscopy (EDS), on a wafer that has been processed in a plasma etch chamber in the manner described above.

To determine when a seasoning process is necessary, the condition of the processing chamber must be evaluated. One method of measuring process chamber conditions is by obtaining an indication of the number of particulates in the upper etch chamber 110. To do this, a monitor wafer with a known particulate count is loaded into the upper etch chamber 110, a monitor wafer process is carried out, and then the monitor wafer is removed and a second particulate count is made on the monitor wafer, using a particulate detection tool, such as a KLA Tencor® particulate detection tool. Depending on the monitor wafer process, when the increase in particulate count exceeds about 20, the etch chamber is typically considered unusable for processing the next wafer. The actual number of particles which is set as a maximum depends on the monitor wafer process and product specifications.

The monitor wafer process may be designed for a given application. One example of a monitor wafer process would be to load a monitor wafer into the process chamber and permit it to stand for a period of time, without providing any gases (either inert or reactive) to the chamber. An alternative monitor wafer process would be to load a monitor wafer into the process chamber and pass inert gas (such as argon) by the wafer, without generating a plasma. A third alternative would be to expose the wafer to a plasma generated from an inert gas. If more rigorous monitoring conditions are desired, the wafer could be exposed to the same gases used in the etch process, with or without generating a plasma from the etchant gases. One skilled in the art will recognize that by altering the monitor wafer process conditions to provide more active and reactive species within the chamber, more particulates may accumulate on the monitor wafer surface. In any case, when one skilled in the art selects a monitor wafer process, it is then necessary to determine what increase in particle count on the monitor wafer is an indication (for that monitor wafer process) that a seasoning process needs to be carried out before any additional wafer substrates are etched.

Eventually, the high particulate-containing etch chamber must be opened for wet cleaning in order to lower the particulate count. If the chamber is opened frequently for cleaning, then the Mean Wafer Between Cleans (MWBC) drops dramatically. Without using the seasoning method of the present invention, the MWBC is as low as 10 wafers or less between cleaning operations, whereas 400 to 500 wafers between cleaning operations is considered economically acceptable.

The chamber seasoning method of the invention is performed in a metal etch chamber for a time period sufficient that a subsequent measurement of particulate count on a monitor silicon wafer indicates an acceptable particulate count. Since noble metals often produce nonvolatile etch byproducts, the seasoning method is particularly useful for noble metal etch chambers, and especially for platinum and iridium etch chambers. As used herein, the terms “platinum” and “iridium” refer to the elements and compounds of the elements, such as oxides.

The present invention provides a method of preventing particulates generated from metal etch byproducts, which are nonvolatile at temperatures at which the metal is etched, from adversely affecting a subsequent metal etch process performed within the same plasma etch chamber. The method includes a seasoning process in which a plasma is used to generate a material which entraps and adheres byproducts from a metal etch process to process chamber walls and internal apparatus surfaces. By adhering metal etch byproduct contaminants to surfaces within the processing chamber, these contaminants are no longer as available to fall upon subsequent wafers (substrates) being processed within the chamber.

Surprisingly, the plasma used to generate the adhering material is generated from a source gas comprising at least one of the principal etchant gases used during the etch process which produced the nonvolatile etch byproducts which have contaminated the etch processing chamber. In addition to the etchant gas species, a source for an entrapment and adhering material is provided. In some instances, upon exposure of a substrate placed in the process chamber during seasoning, an entrapment and adhering material is generated which adheres the nonvolatile etch byproducts to interior chamber surfaces. The entrapment and adhering material may be a carbon-containing or silicon-containing matrix, which is typically generated by reaction of the seasoning plasma with a silicon-containing (such as silicon oxide or silicon nitride) or carbon-containing (such as photoresist) layer on the substrate. Alternatively, the source for the entrapment and adhering material may be a layer of a dielectric material, such as aluminum oxide, which is sputtered off the substrate and which forms a dielectric coating on interior chamber surfaces. A carbon-containing additive gas within the seasoning plasma may optionally provide a source for the entrapment and adhering material. In some instances, a carbon-containing additive gas may be used in the absence of a substrate with an adhering material on its surface.

In a first embodiment of the present invention, a substrate which provides a source of an entrapment and adhering material is placed inside a processing chamber and the substrate (as well as interior surfaces of the chamber) is exposed to a seasoning plasma generated from a source gas that includes at least one principal etchant gas which is typically used to etch a metal from which the byproducts were produced. The seasoning process is carried out at a substrate temperature that is equal to or greater than the substrate temperature at which the metal byproducts are typically produced. The chamber wall temperature is maintained at a temperature which is lower than the substrate temperature. Typically, the temperature of the chamber wall is at least 100° C. to 300° C. lower than the substrate temperature.

When a high temperature (≧250° C.) is used during the seasoning process, the source for the entrapment and adhering material is typically an inorganic material which is stable at temperatures in excess of 250° C. When the seasoning process is performed at a low temperature (<250° C.), the source for the entrapment and adhering material may be an organic material, such as a photoresist.

Typically, the seasoning plasma is generated from a source gas which includes Cl₂, a chlorine-containing compound, or a combination thereof Cl₂ may be used in conjunction with a chlorine-containing compound, such as HCl, BCl₃, SiCl₄, and combinations thereof (by way of example and not by way of limitation). The above-listed chlorine-containing compounds do not dissociate readily into active chlorine species. Therefore, if Cl₂ is used in combination with one or more of these chlorine-containing compounds, the source gas may also include a gas which enhances the dissociation of the chlorine-containing compound into active chlorine species, such as N₂, NH₃, and combinations thereof (by way of example and not by way of limitation). If HCl, BCl₃, SiCl₄, and/or a combination thereof is used without the presence of Cl₂, the source gas must include a chlorine-dissociation-enhancing gas (e.g., N₂ or NH₃).

The seasoning method of the invention is performed for a time period sufficient that a subsequent measurement of particulate count on a monitor silicon wafer indicates an acceptable particulate count. If platinum or iridium is etched within the processing chamber, the method may be performed at a substrate temperature of at least 260° C., for a time period ranging from about 2 minutes to about 30 minutes. If copper is etched within the processing chamber, the method may be performed at a substrate temperature of at least 210° C., for a time period ranging from about 2 minutes to about 30 minutes. If a nickel-iron alloy, cobalt-iron alloy, or nickel-iron-cobalt alloy is etched within the processing chamber, the method may be performed at a substrate temperature of at least 25° C., for a time period ranging from about 2 minutes to about 30 minutes. The temperature of the substrate is typically about 10° C. to about 40° C. higher than the temperature of the cathode, due to ion bombardment of the substrate during a plasma etch process.

If the chamber has just been wet-cleaned, the seasoning method of the invention should be performed for a time period at the high end of the range stated above (i.e., about 20 to 30 minutes) in order to build up an adhering coating on interior surfaces of the chamber. If the chamber has been previously seasoned, the seasoning method may be performed for a time period at the lower end of the range stated above (i.e., about 2 to 5 minutes).

In a particular embodiment of applicants' method, a substrate present in the chamber during seasoning provides a source of a dielectric material, such as silicon oxide, silicon nitride, or aluminum oxide, by way of example and not by way of limitation. The chamber walls, internal apparatus surfaces, and the substrate are then exposed to a seasoning plasma generated from a source gas comprising Cl₂, a chlorine-containing compound, or a combination thereof.

The substrate is typically a silicon wafer coated with a layer of a material selected from the group consisting of silicon oxide, silicon nitride, aluminum oxide, and combinations thereof. A bare silicon wafer is not used in conjunction with a chlorine-based seasoning process, as this may result in generation of, and contamination of the chamber with, silicon particles. Thus, if the coating is completely removed, and bare silicon is exposed during the seasoning process, this may result in the undesirable generation of silicon particles.

The layer of coating on the silicon wafer is typically at least 3000 Å thick. In one embodiment, a silicon oxide-coated silicon wafer is loaded into the chamber, and the seasoning process is performed for a period of about 2 minutes. Then, a second silicon oxide-coated wafer is loaded into the chamber, and the seasoning process is performed for another 2 minutes, for a total seasoning time of 4 minutes. Approximately 1500 Å of silicon oxide is typically removed from each wafer during a 2-minute seasoning step. If the coating on the wafer is thick enough (i.e., at least 4000-5000 Å thick), the seasoning process can be performed for 4 minutes using a single wafer, avoiding the need to unload a first wafer and load a second wafer. If the coating on each wafer is thinner than about 3000 Å, three or more wafers should be used, dividing the total seasoning time by the relative thickness of the coating on each wafer. Dielectric material sputtered from the surface of the substrate adheres the metal-comprising etch byproducts to chamber surfaces.

In a particular embodiment of applicants' seasoning method, the seasoning plasma is generated from Cl₂, optionally in combination with a noble gas, such as argon, helium, xenon, krypton, and combinations thereof. The seasoning plasma is typically generated from a gas mixture of Cl₂ and argon, where Cl₂ comprises about 50 to about 90 volume %, and argon comprises about 10 to about 50 volume %, of the gas mixture. Typically, Cl₂ comprises about 60 to about 80 volume %, and argon comprises about 20 to about 40 volume %, of the gas mixture.

The seasoning plasma may also include N₂. When the plasma source gas mixture includes N₂, the gas mixture typically comprises about 40 to about 90 volume % Cl₂, about 10 to about 50 volume % argon, and about 1 to about 20 volume % N₂. More typically, the gas mixture comprises about 60 to about 80 volume % Cl₂, about 10 to about 30 volume % argon, and about 5 to about 20 volume % N₂.

Table One, below, presents typical process conditions for performing applicants' chamber seasoning method, when a silicon oxide-coated silicon wafer is used as the substrate, and the seasoning gas mixture comprises Cl₂, N₂, and argon.

TABLE ONE
Typical Process Conditions for Seasoning a Plasma Processing
Chamber After a Metal Etch Process

| | | | Optimum |
|---|---|---|---|
| | Range of | Typical | Known |
| | Process | Process | Process |
| Process Parameter | Conditions | Conditions | Conditions |
| Cl₂ (sccm) | 40-200 | 100-140 | 110-130 |
| N₂ (sccm) | 0-40 | 5-25 | 10-20 |
| Ar (sccm) | 0-100 | 10-50 | 20-40 |
| Total Gas Flow (sccm) | 50-250 | 120-210 | 150-180 |
| Plasma Source Power (W) | 400-1400 | 700-1100 | 800-1000 |
| Substrate Bias Power (W) | 150-400 | 200-350 | 250-300 |
| Process Chamber Pressure | 5-50 | 15-25 | 18-22 |
| (mTorr) | | | |
| Substrate Temperature (° C.) | 250-400 | 300-370 | 310-360 |
| Cathode Temperature (° C.) | 240-390 | 290-360 | 300-350 |
| Dome Temperature (° C.) | 50-400 | 60-120 | 80 -100 |
| Wall Temperature (° C.) | 20-150 | 40-100 | 60-80 |
| Total Seasoning Time (sec) | 120-600 | 180-300 | 220 -260 |

The processing conditions shown in the right-hand column of Table One have been shown to result in a particle count reduction from greater than 100 to less than 20 particles per wafer.

The chamber seasoning method of the invention which employs a source of a dielectric material is believed to function by the creation of a dielectric material which accumulates on process chamber surfaces and entraps and adheres metal particulates to the chamber surfaces, preventing the particulates from flaking off of chamber surfaces during subsequent etch processes, while providing a renewed dielectric chamber surface which enables more uniform plasma processing conditions. Further, the use of a seasoning plasma generated from an etchant gas which is typically used to etch the metal is believed to alter the metal such that it is more amenable to adhering to chamber surfaces.

In a second embodiment of the chamber seasoning method of the invention, interior surfaces of the processing chamber are exposed to a seasoning plasma generated from a gas mixture comprising at least two gases selected from the group consisting of BCl₃, HBr, and CF_{4,}, for a time period sufficient that a subsequent measurement of particulate count on a monitor silicon wafer indicates an acceptable particulate count. In this embodiment, CF₄ is added to the plasma source gas to provide for polymer formation which entraps and adheres metal etch byproduct contaminants to chamber apparatus surfaces. A substrate including a layer of iridium is placed in the plasma etch chamber and exposed to the seasoning plasma. CF₄ from the seasoning plasma generates a carbon-containing matrix which entraps iridium particulates generated during the seasoning process and metal particulates already in the chamber from previous etch processes and adheres these particulates to chamber surfaces. Thus, a uniform carbon-metal matrix is formed on surfaces of the processing chamber, enabling stable plasma processing conditions.

In a particular embodiment, a dummy wafer having an Ir layer thereon is placed within upper chamber 110, and a seasoning gas mixture of BCl₃, HBr, CF₄, and Ar is injected into upper chamber 110 through the gas injection nozzles 118 during etch chamber preparation for the next wafer processing operation. The four gases are stored in separate reservoirs 154, fed into a gas mixing block 150, then injected into upper etch chamber 110 through gas injection nozzles 118. While the particular embodiment described above used four gases, seasoning of the chamber according to the present embodiment can be accomplished using two or more gases. For example, combinations such as BCl₃ and CF₄ can be used.

Process variables for performing the chamber seasoning method of the invention, such as gas flow rates, process chamber pressure, process chamber temperature, wafer carrier (cathode) temperature, and applied RF power levels can be selected to achieve optimal chamber seasoning. For example, the seasoning gases consisting of BCl₃, HBr, CF₄, and Ar are delivered to gas mixing block 150 by means of four mass flow rate meters 152, typically at rates of 30 sccm, 30 sccm, 30 sccm, and 40 sccm, respectively. The seasoning gases may be injected into the etch chamber 110 at flow rates which are different from those listed above, resulting in varying particulate controlling efficiencies. One skilled in the art will be able to optimize seasoning gas flow rates for given operating environments with minimal experimentation.

The process chamber pressure is typically maintained within a range of about 5 mTorr to about 10 mTorr. Particularly good results were obtained using a process chamber pressure of 8 mTorr. After injecting the seasoning gas mixture, the source power from the source RF generator 132 and the bias power from the bias RF generator 130 are applied for about 30-120 seconds, typically about 45 seconds, in order to generate a seasoning plasma within etch chamber 110.

Typically, the plasma source power applied during seasoning is within the range of about 1000 W to about 1400 W. The bias power applied to the cathode is typically within the range of about 150 W to about 250 W. Satisfactory results were obtained using a DPS chamber with a source power of 1400 W and a bias power of 200 W. During performance of the seasoning process, the cathode 124 was maintained at a temperature of 45° C., and the chamber wall and dome were maintained at a temperature of 80° C. The dummy wafer was cooled by flowing helium gas with a pressure of 4 Torr between the wafer and an electrostatic chuck that holds the wafer onto the cathode.

An exemplary embodiment process for testing and seasoning a DPS metal etch chamber using a BCl₃/HBr/CF₄/Ar seasoning gas mixture includes the following steps:

1) Measure a particulate count on a monitor wafer inspected with an inspection tool. The monitor wafer is processed in the etch chamber for a time period ranging from about 60 seconds to about 110 seconds to perform the measurement.

2) If the measured particulate count is greater than 20 particulates per wafer, place a dummy wafer having an Ir layer in the metal etch chamber and season the metal etch chamber using a seasoning plasma generated from a BCl₃/HBr/CF₄/Ar gas mixture. After seasoning, purge the etch chamber of the remaining gas mixture.

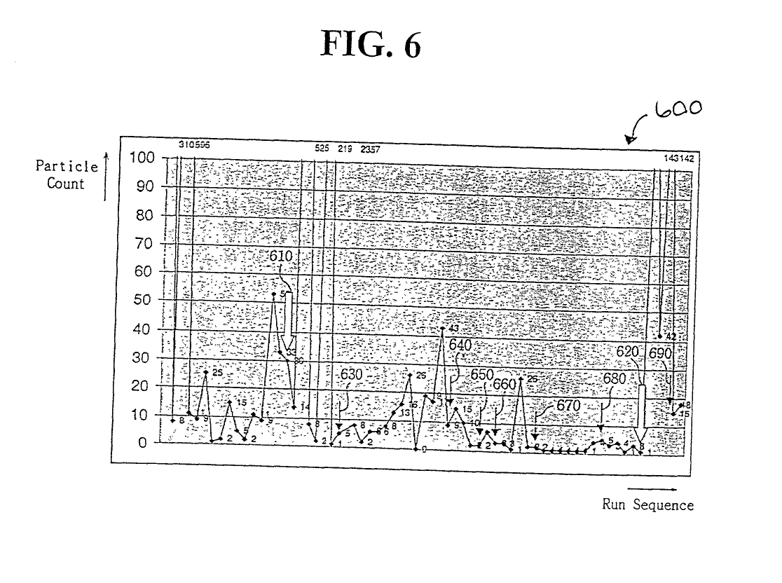

FIG. 6 is a graph 600 showing changes in iridium particulate counts over time, as cleaning and seasoning of the etch chamber are performed in accordance with the present invention. The first etch chamber cleaning took place at sequence point 610 (indicated by the white arrow). Cleaning was performed according to a standard cleaning process, in which the inner surfaces of the upper chamber 110 and dome 104 were wiped off with a wet cloth in order to remove the Ir particulates adhered to the inner surface of the etch chamber Despite the fact that the particulates on the inner surfaces of the upper chamber 110 and dome 104 were thoroughly wiped off, the Ir particulate count on a dummy wafer after subsequent etching was significant.

At sequence point 630, a first seasoning was performed using a gas mixture of BCl₃, HBr, CF₄, and argon. A wafer subsequently etched in the seasoned chamber had a particulate count below 10. However, as more wafers were processed, the particulate count reached 26, exceeding the upper limit of 20. Several more wafers were processed, until a particulate count of 43 was reached. At this time, another seasoning operation was performed. Following seasoning, the particulate count dropped below 20. Additional seasoning operations were performed at sequence points 650, 660, 670, and 680. The wafers etched after these seasoning operations each had only a few particulates.

In order to evaluate the effects of not seasoning the chamber, another standard wet cleaning operation of the inner surfaces of upper chamber 110 and dome 104 was performed at sequence point 620, even though the particulate count at the time was well below the upper limit of 20. The result was another substantial particulate count, as expected. Almost immediately after performance of the wet cleaning operation at sequence point 620, another seasoning operation was performed at sequence point 690. The particulate count dropped to 15, well below the upper limit of 20.

The experimental data described above with reference to FIG. 6 indicate that seasoning of the etch chamber using a mixture of BCl₃, HBr, CF₄, and argon gases reduces particulate counts significantly. When the seasoning operation is performed as needed, the particulate counts of etched wafers in the DPS chamber 100 can be assured to be sustainably well below the upper limit of 20.

Contaminants generated during the etching of wafers having iridium layers are predominantly iridium particulates. Because iridium, as a noble metal, does not react well with other chemicals, iridium particulates generated during an etch process are not readily removed by a subsequent purge operation or by chemical means. However, we have demonstrated that seasoning of a plasma etch chamber using a seasoning plasma generated from a mixture of gases consisting of BCl₃, HBr, CF₄, and argon is very effective at reducing the amount of iridium particulates remaining in the etch chamber after a metal etch process.

BCl₃ and HBr are vaporized from the liquid state. These gases produce massive amounts of polymer particulates and byproducts in the plasma state. Since the vaporized BCl₃ and HBr gases are “wet” or “damp” in the gaseous state, these polymers and byproducts have good adhesion to the ceramic dome and wall surfaces of the plasma etch chamber. Therefore, these gases force the iridium particulates to adhere to inner surfaces of the upper chamber 110 of the DPS etch chamber 100. It is believed that the polymers and byproducts interact with each other to absorb a significant quantity of iridium particulates, so that the iridium particulates can be readily purged from the upper chamber 110. It is also believed that the iridium particulates remaining in the upper chamber are forced to adhere to the inner surfaces of the upper chamber walls, as well as to the ceramic dome. As a result, the seasoning plasma effectively and significantly reduces the amount of undesirable and detrimental iridium particulates.

The present invention provides a method of preventing particulates generated from metal etch byproducts which are nonvolatile at temperatures at which the metal is etched from adversely affecting a subsequent etch process performed in a plasma etch chamber.

The above described exemplary embodiments are not intended to limit the scope of the present invention, as one skilled in the art can, in view of the present disclosure expand such embodiments to correspond with the subject matter of the invention claimed below.

We claim:

1. A method of preventing iridium particulates generated during etching of a layer of iridium or an iridium compound in a plasma etch chamber from adversely affecting an etch process subsequently performed in said plasma etch chamber, wherein said method comprises exposing interior surfaces of said plasma etch chamber to a seasoning plasma generated from a gas mixture comprising at least two gases selected from the group consisting of BCl₃, HBr, and CF₄.

2. The method of claim 1, wherein said method further includes the step of placing a dummy wafer having at least one iridium layer formed thereon in said plasma etch chamber prior to prior to exposing surfaces of said chamber to said seasoning plasma.

3. The method of claim 1, wherein said plasma etch chamber is a decoupled plasma source etch chamber.

4. The method of claim 3, wherein a plasma source power within the range of about 1000 W to about 1400 W and a substrate bias power within the range of about 150 W to about 250 W are applied during generation of said seasoning plasma.

5. The method of claim 4, wherein said plasma source power and said substrate bias power are applied for a time period within the range of about 30 seconds to about 120 seconds.

6. The method of claim 1, wherein said gas mixture additionally includes argon.

7. The method of claim 6, wherein said BCl₃ is provided at a flow rate of 30 sccm, said HBr is provided at a flow rate of 30 sccm, said CF₄ is provided at a flow rate of 30 sccm, and said argon is provided at a flow rate of 40 sccm, to said plasma etch chamber.

8. The method of claim 7, wherein a process chamber pressure within said plasma etch chamber is maintained within the range of about 5 mTorr to about 10 mTorr.

9. The method of claim 1, wherein said method further includes the step of cleaning the plasma etch chamber with a purge gas prior to exposing surfaces of said chamber to said seasoning plasma.

10. The method of claim 1, wherein said method further includes the step of purging said plasma etch chamber of remaining seasoning gas mixture after surfaces of said chamber to said seasoning plasma.

11. A method of forming a storage capacitor in a plasma etch chamber, comprising the steps of:
a) exposing interior surfaces of said plasma etch chamber to a seasoning plasma generated from a gas mixture comprising at least two gases selected from the group consisting of BCl₃, HBr, and CF₄;
b) purging said plasma etch chamber of remaining seasoning gas mixture;
c) loading a substrate having at least one iridium layer formed thereon into said plasma etch chamber; and
d) plasma etching said at least one iridium layer.

12. The method of claim 11, wherein said method further includes the step of placing a dummy wafer having at least one iridium layer formed thereon in said plasma etch chamber prior to prior to exposing surfaces of said chamber to said seasoning plasma.

13. The method of claim 11, wherein said plasma etch chamber is a decoupled plasma source etch chamber.

14. The method of claim 13, wherein a plasma source power within the range of about 1000 W to about 1400 W and a substrate bias power within the range of about 150 W to about 250 W are applied during generation of said seasoning plasma.

15. The method of claim 14, wherein said plasma source power and said substrate bias power are applied for a time period within the range of about 30 seconds to about 120 seconds.

16. The method of claim 11, wherein said gas mixture additionally includes argon.

17. The method of claim 16, wherein said BCl₃ is provided at a flow rate of 30 sccm, said HBr is provided at a flow rate of 30 sccm, said CF₄ is provided at a flow rate of 30 sccm, and said argon is provided at a flow rate of 40 sccm, to said plasma etch chamber.

18. The method of claim 17, wherein a process chamber pressure within said plasma etch chamber is maintained within the range of about 5 mTorr to about 10 mTorr.

19. A method of forming a storage capacitor in a plasma etch chamber, comprising the steps of:
a) loading a substrate having at least one iridium layer formed thereon into said plasma etch chamber;
b) plasma etching said at least one iridium layer;
c) removing said substrate from said plasma etch chamber;
d) cleaning said plasma etch chamber using a purge gas; and
e) exposing interior surfaces of said plasma etch chamber to a seasoning plasma generated from a gas mixture comprising at least two gases selected from the group consisting of BCl₃, HBr, and CF₄.

20. The method of claim 19, wherein said method further includes the step of placing a dummy wafer having at least one iridium layer formed thereon in said plasma etch chamber prior to prior to exposing surfaces of said chamber to said seasoning plasma.

21. The method of claim 20, wherein said plasma etch chamber is a decoupled plasma source etch chamber.

22. The method of claim 21, wherein a plasma source power within the range of about 1000 W to about 1400 W and a substrate bias power within the range of about 150 W to about 250 W are applied during generation of said seasoning plasma.

23. The method of claim 22, wherein said plasma source power and said substrate bias power are applied for a time period within the range of about 30 seconds to about 120 seconds.

24. The method of claim 19, wherein said gas mixture additionally includes argon.

25. The method of claim 24, wherein said BCl₃ is provided at a flow rate of 30 sccm, said HBr is provided at a flow rate of 30 sccm, said CF₄ is provided at a flow rate of 30 sccm, and said argon is provided at a flow rate of 40 sccm, to said plasma etch chamber.

26. The method of claim 25, wherein a process chamber pressure within said plasma etch chamber is maintained within the range of about 5 mTorr to about 10 mTorr.

27. A method of preventing platinum particulates generated during etching of a layer of platinum in a plasma etch chamber from adversely affecting an etch process subsequently performed in said plasma etch chamber, wherein said method comprises exposing interior surfaces of said plasma etch chamber to a seasoning plasma generated from a gas mixture comprising at least two gases selected from the group consisting of BCl₃, HBr, and CF₄.

28. The method of claim 27, wherein said platinum particulates are generated during etching of an electrode which includes platinum, iridium oxide (IrO₂), and iridium layers.

29. The method of claim 27, wherein said gas mixture additionally includes argon.

30. A method of preventing particulates generated from metal etch byproducts, which are nonvolatile at a substrate temperature at which said metal is etched, from adversely affecting an etch process subsequently performed in a plasma etch chamber in which said metal was etched, wherein said method comprises:
a) placing a substrate in said plasma etch chamber; and
b) exposing said substrate, chamber walls, and internal apparatus surfaces of said plasma etch chamber to a seasoning plasma generated from a source gas that includes at least one principal etchant gas used during an etch process which produced said nonvolatile etch byproducts, at a substrate temperature that is equal to or greater than a substrate temperature at which said nonvolatile etch byproducts were produced,
wherein exposure of said substrate to said seasoning plasma generates an entrapment and adhering material which adheres said nonvolatile etch byproducts to chamber walls and internal apparatus surfaces.

31. The method of claim 30, wherein said substrate includes a material which provides a source for said entrapment and adhering material.

32. The method of claim 31, wherein said substrate includes an inorganic material which provides a source for said entrapment and adhering material.

33. The method of claim 32, wherein said method is performed at a substrate temperature of 250° C. or greater.

34. The method of claim 32, wherein said method is performed at a substrate temperature less than 250° C.

35. The method of claim 31, wherein said substrate includes an organic material which provides a source for said entrapment and adhering material, and wherein said method is performed at a substrate temperature less than 250° C.

36. The method of claim 30, wherein said seasoning plasma includes a gas which provides a source for said entrapment and adhering material.

37. The method of claim 37, wherein said seasoning plasma includes a carbon-containing gas.

38. A method of preventing particulates generated from metal etch byproducts, which are nonvolatile at a substrate temperature at which said metal is etched, from adversely affecting an etch process subsequently performed in a plasma etch chamber in which said metal was etched, wherein said method comprises:
a) placing a substrate which includes a material which provides a source for an entrapment and adhering material; and
b) exposing said substrate, chamber walls, and internal apparatus surfaces of said plasma etch chamber to a seasoning plasma generated from a gas selected from the group consisting of Cl₂, a chlorine-containing compound, and combinations thereof, at a substrate temperature that is equal to or greater than a substrate temperature at which said nonvolatile etch byproducts were produced,
wherein exposure of said substrate to said seasoning plasma generates said entrapment and adhering material which adheres said nonvolatile etch byproducts to chamber walls and internal apparatus surfaces.

39. The method of claim 38, wherein said substrate includes an inorganic material which provides a source for said entrapment and adhering material.

40. The method of claim 39, wherein said inorganic material is a dielectric selected from the group consisting of silicon oxide, silicon nitride, aluminum oxide, and combinations thereof.

41. The method of claim 39, wherein said method is performed at a substrate temperature of 250° C. or greater.

42. The method of claim 41, wherein a metal which is etched within said plasma etch chamber is selected from the group consisting of platinum, iridium, and combinations thereof, and wherein said method is performed at a substrate temperature of at least 260° C., for a time period ranging from about 2 minutes to about 30 minutes.

43. The method of claim 39, wherein said method is performed at a substrate temperature less than 250° C.

44. The method of claim 43, wherein a metal which is etched in said plasma etch chamber is copper, and wherein said method is performed at a substrate temperature of at least 210° C., for a time period ranging from about 2 minutes to about 30 minutes.

45. The method of claim 43, wherein a metal which is etched in said plasma etch chamber is selected from the group consisting of a nickel-iron alloy, a cobalt-iron alloy, and a nickel-iron-cobalt alloy, and wherein said method is performed at a substrate temperature of at least 25° C., for a time period ranging from about 2 minutes to about 30 minutes.

46. The method of claim 38, wherein said substrate includes an organic material which provides a source for said entrapment and adhering material, and wherein said method is performed at a substrate temperature less than 250° C.

47. The method of claim 46, wherein said organic material is a photoresist.

48. A method of preventing particulates generated from metal etch byproducts, which are nonvolatile at a substrate temperature at which said metal is etched, from adversely affecting an etch process subsequently performed in a plasma etch chamber in which said metal was etched, wherein said method comprises:
a) placing a substrate which provides a source of a dielectric material in said plasma etch chamber; and
b) exposing said substrate, chamber walls, and internal apparatus surfaces of said plasma etch chamber to a seasoning plasma generated from a gas selected from the group consisting of Cl₂, a chlorine-containing compound, and combinations thereof, at a substrate temperature that is equal to or greater than a substrate temperature at which said nonvolatile etch byproducts were produced,
wherein exposure of said substrate to said seasoning plasma generates said dielectric material which adheres said nonvolatile etch byproducts to chamber walls and internal apparatus surfaces.

49. The method of claim 48, wherein said metal is selected from the group consisting of platinum, iridium, copper, a nickel-iron alloy, a cobalt-iron alloy, a nickel-iron-cobalt alloy, and combinations thereof.

50. The method of claim 48, wherein said dielectric material is selected from the group consisting of silicon oxide, silicon nitride, aluminum oxide, and combinations thereof.

51. The method of claim 48, wherein said seasoning plasma further includes a noble gas selected from the group consisting of argon, helium, xenon, krypton, and combinations thereof.

52. The method of claim 51, wherein said seasoning plasma is generated from a gas mixture comprising Cl₂ and argon, wherein Cl₂ comprises about 50 to about 90 volume %, and argon comprises about 10 to about 50 volume %, of said gas mixture.

53. The method of claim 52, wherein Cl₂ comprises about 60 to about 80 volume %, and argon comprises about 20 to about 40 volume %, of said gas mixture.

54. The method of claim 51, wherein said seasoning plasma is generated from a gas mixture comprising Cl₂, argon, and N₂, wherein Cl₂ comprises about 40 to about 90 volume %, argon comprises about 10 to about 50 volume %, and N₂ comprises about 1 to about 20 volume %, of said gas mixture.

55. The method of claim 54, wherein Cl₂ comprises about 60 to about 80 volume %, argon comprises about 10 to about 30 volume %, and N₂ comprises about 5 to about 20 volume %, of said gas mixture.

56. The method of claim 48, wherein said seasoning plasma is generated from a source gas comprising Cl₂ and a chlorine-containing compound selected from the group consisting of HCl, BCl₃, SiCl₄, and combinations thereof.

57. The method of claim 56, wherein said source gas further includes a gas which enhances dissociation of said chlorine-containing compound into active chlorine species.

58. The method of claim 57, wherein said chlorine-dissociation-enhancing gas is selected from the group consisting of N₂, NH₃, and combinations thereof.

59. The method of claim 48, wherein said seasoning plasma is generated from a source gas comprising a chlorine-containing compound selected from the group consisting of HCl, BCl₃, SiCl₄, and combinations thereof, and wherein said source gas further includes a gas which enhances dissociation of said chlorine-containing compound into active chlorine species.

60. The method of claim 59, wherein said chlorine-dissociation-enhancing gas is selected from the group consisting of N₂, NH₃, and combinations thereof.
